(19) United States
(12) Patent Application Publication
(10) Pub. No.: US 2024/0422990 A1
(43) Pub. Date: Dec. 19, 2024

(54) SEMICONDUCTOR DEVICE AND MANUFACTURING METHOD THEREFOR

(71) Applicant: XIAMEN INDUSTRIAL TECHNOLOGY RESEARCH INSTITUTE CO., LTD., Xiamen (CN)

(72) Inventors: Taiwei CHIU, Xiamen (CN); Szu-chun KANG, Xiamen (CN); Yajun ZHANG, Xiamen (CN); Yu LIU, Xiamen (CN)

(73) Assignee: XIAMEN INDUSTRIAL TECHNOLOGY RESEARCH INSTITUTE CO., LTD., Xiamen (CN)

(21) Appl. No.: 18/687,308

(22) PCT Filed: Aug. 29, 2022
(86) PCT No.: PCT/CN2022/115381

§ 371 Date: Feb. 28, 2024

(30) Foreign Application Priority Data
Dec. 22, 2021 (CN) 202111582275.7

(51) Int. Cl. H10B 63/00; H10N 70/00

(52) U.S. Cl. CPC H10B 63/22; H10N 70/066; H10N 70/841

(57) ABSTRACT

A semiconductor device and a manufacturing method therefor are provided. The method includes: depositing a first dielectric layer material on a semiconductor substrate, and etching the first dielectric layer material to form a trench corresponding to each via in the semiconductor substrate in a first dielectric layer; the via being filled with a metal material; depositing a bottom electrode material in the trench, and etching the bottom electrode material to form a bottom electrode covering a bottom of the trench; depositing a resistive layer material to form a resistive layer covering an upper surface of the bottom electrode and a sidewall of the trench; and depositing a top electrode material in a groove of the resistive layer, such that the groove is filled with the top electrode material to form a top electrode which is arranged in the groove and fills the groove.

### CROSS-REFERENCE TO THE RELATED APPLICATIONS

This application is the national phase entry of International Application No. PCT/CN2022/115381, filed on Aug. 29, 2022, which is based upon and claims priority to Chinese Patent Application No. 202111582275.7, filed on Dec. 22, 2021, the entire contents of which are incorporated herein by reference.

### TECHNICAL FIELD

The present application relates to the field of semiconductor technologies, and in particular, to a semiconductor device and a manufacturing method therefor.

### BACKGROUND

In the related art, a resistive random access memory (RRAM) is one of the most promising next-generation nonvolatile memories. Compared with a conventional floating gate flash memory, the RRAM has obvious advantages in terms of a device structure, a speed, scalability, a three-dimensional integration potential, and the like.

A basic structure of the RRAM is a metal-insulator-metal (MIM) structure, mainly including a bottom electrode, a resistive layer, and a top electrode. The resistive layer is made of various oxide thin film materials, and may be converted reversely between different resistance states under an action of an electric signal such as an applied voltage or current. Such reversible conversion is mostly implemented by forming and breaking a conductive filament.

Currently, the RRAM is manufactured in the following manner: after the MIM structure is deposited, a resistive structure (R) is generated after etching, and the resistive structure is a stack structure, as shown in FIG. 1. A density of the RRAM of the stack structure is not high, and performance of the whole device is not high.

This is because a width of the R of the RRAM manufactured in this manner cannot be excessively small. If the width is excessively small, a contact area between the R and a semiconductor substrate is excessively small, thereby increasing a risk that the R falls off. Therefore, a size of the R is large enough to maintain stability of the RRAM. In addition, a pitch between one R and another R cannot be excessively small. Otherwise, a gap is generated when an oxide is filled, and the gap increases a risk of bridging between M1 and M2 (M1 and M2 are respectively metal layers connected to the R). Therefore, a large pitch and a large volume result in a low density of the RRAM of the stack structure.

### SUMMARY

Embodiments of the present application are intended to provide a semiconductor device and a manufacturing method therefor, to resolve the above technical problems.

According to a first aspect, the present disclosure provides a method for manufacturing a semiconductor device. The method includes: depositing a first dielectric layer material on a semiconductor substrate, and etching the first dielectric layer material to form a trench corresponding to each via in the semiconductor substrate in a first dielectric layer, the via being filled with a metal material; depositing a bottom electrode material in the trench, and etching the bottom electrode material to form a bottom electrode covering a bottom of the trench; depositing a resistive layer material to form a resistive layer covering an upper surface of the bottom electrode and a sidewall of the trench; and depositing a top electrode material in a groove of the resistive layer, such that the groove is filled with the top electrode material to form a top electrode which is arranged in the groove and fills the groove.

The method may further include: performing planarization, such that an upper surface of the first dielectric layer is flush with an upper surface of the resistive layer and an upper surface of the top electrode in the trench.

According to the first aspect of the present disclosure, a semiconductor device is further provided, and the semiconductor device includes: a semiconductor substrate, a first dielectric layer, a bottom electrode, a resistive layer, and a top electrode; the semiconductor substrate includes multiple vias filled with a metal material; the first dielectric layer is arranged on the semiconductor substrate, multiple trenches are formed in the first dielectric layer, and the trenches are in a one-to-one correspondence with the vias; the bottom electrode covers a bottom of the trench, and a lower surface of the bottom electrode contacts an upper surface of a corresponding via; the resistive layer covers an upper surface of the bottom electrode and a sidewall of the trench; and the top electrode is arranged in a groove of the resistive layer and fills the groove.

An upper surface of the first dielectric layer may be flush with an upper surface of the resistive layer and an upper surface of the top electrode in the trench.

According to a second aspect of the present disclosure, a method for manufacturing a semiconductor device is provided, and the method includes: depositing a first dielectric layer material on a semiconductor substrate, and etching the first dielectric layer material to form a trench corresponding to each via in the semiconductor substrate in a first dielectric layer, the via being filled with a metal material; depositing a bottom electrode material in the trench, and etching the bottom electrode material to form a bottom electrode covering a bottom of the trench; depositing a resistive layer material to form a resistive layer covering an upper surface of the bottom electrode and a sidewall of the trench; depositing a second dielectric layer material or a thermally enhanced layer material in a groove of the resistive layer, and etching the second dielectric layer material or the thermally enhanced layer material to form a second dielectric layer or a thermally enhanced layer covering a sidewall of the groove; and filling a top electrode material in a cavity formed by the second dielectric layer or the thermally enhanced layer and the resistive layer to form a top electrode.

The method may further include: performing planarization, such that an upper surface of the first dielectric layer is flush with an upper surface of the resistive layer, an upper surface of the top electrode, and an upper surface of the second dielectric layer or the thermally enhanced layer in the trench.

According to the second aspect of the present disclosure, a semiconductor device is further provided, and the semiconductor device includes: a semiconductor substrate, a first dielectric layer, a bottom electrode, a resistive layer, and a top electrode, and further includes: a second dielectric layer or a thermally enhanced layer; the semiconductor substrate includes multiple vias filled with a metal material; the first dielectric layer is arranged on the semiconductor substrate, multiple trenches are formed in the first dielectric layer, and the trenches are in a one-to-one correspondence with the vias; the bottom electrode covers a bottom of the trench, and a lower surface of the bottom electrode contacts an upper surface of a corresponding via; the resistive layer covers an upper surface of the bottom electrode and a sidewall of the trench; the second dielectric layer or the thermally enhanced layer covers a sidewall of a groove of the resistive layer, and a cavity is formed; and the top electrode is arranged in the cavity and fills the cavity.

An upper surface of the first dielectric layer may be flush with an upper surface of the resistive layer, an upper surface of the top electrode, and an upper surface of the second dielectric layer or the thermally enhanced layer in the trench.

According to a third aspect of the present disclosure, a method for manufacturing a semiconductor device is provided, and the method includes: depositing a first dielectric layer material on a semiconductor substrate, and etching the first dielectric layer material to form a trench corresponding to each via in the semiconductor substrate in a first dielectric layer, the via being filled with a metal material; depositing a bottom electrode material in the trench, and etching the bottom electrode material to form a bottom electrode covering a bottom of the trench; depositing a resistive layer material to form a resistive layer covering an upper surface of the bottom electrode and a sidewall of the trench; depositing a top electrode material in a groove of the resistive layer to form a top electrode covering a bottom and a sidewall of the groove of the resistive layer; and filling a second dielectric layer material in a groove of the top electrode to form a second dielectric layer.

The method may further include: performing planarization, such that an upper surface of the first dielectric layer is flush with an upper surface of the resistive layer, an upper surface of the top electrode, and an upper surface of the second dielectric layer in the trench.

According to the third aspect of the present disclosure, a semiconductor device is further provided, and the semiconductor device includes: a semiconductor substrate, a first dielectric layer, a bottom electrode, a resistive layer, a top electrode, and a second dielectric layer; the semiconductor substrate includes multiple vias filled with a metal material; the first dielectric layer is arranged on the semiconductor substrate, multiple trenches are formed in the first dielectric layer, and the trenches are in a one-to-one correspondence with the vias; the bottom electrode covers a bottom of the trench, and a lower surface of the bottom electrode contacts an upper surface of a corresponding via; the resistive layer covers an upper surface of the bottom electrode and a sidewall of the trench; the top electrode covers a bottom and a sidewall of a groove of the resistive layer; and the second dielectric layer is filled in a groove of the top electrode.

An upper surface of the first dielectric layer may be flush with an upper surface of the resistive layer, an upper surface of the top electrode, and an upper surface of the second dielectric layer in the trench.

According to a fourth aspect of the present disclosure, a method for manufacturing a semiconductor device is provided, and the method includes: depositing a first dielectric layer material on a semiconductor substrate, and etching the first dielectric layer material to form a trench corresponding to each via in the semiconductor substrate in a first dielectric layer, the via being filled with a metal material; depositing a bottom electrode material in the trench, and etching the bottom electrode material to form a bottom electrode covering a bottom of the trench; depositing a resistive layer material to form a resistive layer covering an upper surface of the bottom electrode and a sidewall of the trench; depositing a top electrode material in a groove of the resistive layer, and etching the top electrode material to form a top electrode covering a sidewall of the groove of the resistive layer; and filling a second dielectric layer material in a cavity formed by the top electrode and the resistive layer to form a second dielectric layer.

The method may further include: performing planarization, such that an upper surface of the first dielectric layer is flush with an upper surface of the resistive layer, an upper surface of the top electrode, and an upper surface of the second dielectric layer in the trench.

According to the fourth aspect of the present disclosure, a semiconductor device is further provided, which includes: a semiconductor substrate, a first dielectric layer, a bottom electrode, a resistive layer, a top electrode, and a second dielectric layer; the semiconductor substrate includes multiple vias filled with a metal material; the first dielectric layer is arranged on the semiconductor substrate, multiple trenches are formed in the first dielectric layer, and the trenches are in a one-to-one correspondence with the vias; the bottom electrode covers a bottom of the trench, and a lower surface of the bottom electrode contacts an upper surface of a corresponding via; the resistive layer covers an upper surface of the bottom electrode and a sidewall of the trench; the top electrode covers a sidewall of a groove of the resistive layer; and the second dielectric layer is filled in a cavity formed by the top electrode and the resistive layer.

An upper surface of the first dielectric layer may be flush with an upper surface of the resistive layer, an upper surface of the top electrode, and an upper surface of the second dielectric layer in the trench.

According to a fifth aspect of the present disclosure, a method for manufacturing a semiconductor device is provided, and the method includes: depositing a first dielectric layer material on a semiconductor substrate, and etching the first dielectric layer material to form a trench corresponding to each via in the semiconductor substrate in a first dielectric layer, the via being filled with a metal material; depositing a bottom electrode material in the trench, and etching the bottom electrode material to form a bottom electrode covering a bottom of the trench; depositing a resistive layer material to form a resistive layer covering an upper surface of the bottom electrode and a sidewall of the trench; depositing a thermally enhanced layer material in a groove of the resistive layer to form a thermally enhanced layer covering a bottom and a sidewall of the groove of the resistive layer; and filling a top electrode material in a groove of the thermally enhanced layer to form a top electrode.

The method may further include: performing planarization, such that an upper surface of the first dielectric layer is flush with an upper surface of the resistive layer, an upper surface of the top electrode, and an upper surface of the thermally enhanced layer in the trench.

According to the fifth aspect of the present disclosure, a semiconductor device is further provided, which includes: a semiconductor substrate, a first dielectric layer, a bottom electrode, a resistive layer, a top electrode, and a thermally enhanced layer; the semiconductor substrate includes multiple vias filled with a metal material; the first dielectric layer is arranged on the semiconductor substrate, multiple trenches are formed in the first dielectric layer, and the trenches are in a one-to-one correspondence with the vias; the bottom electrode covers a bottom of the trench, and a lower surface of the bottom electrode contacts an upper surface of a corresponding via; the resistive layer covers an upper surface of the bottom electrode and a sidewall of the trench; the thermally enhanced layer covers a bottom and a sidewall of a groove of the resistive layer; and the top electrode is filled in a groove of the thermally enhanced layer.

An upper surface of the first dielectric layer may be flush with an upper surface of the resistive layer, an upper surface of the top electrode, and an upper surface of the thermally enhanced layer in the trench.

The trench-type resistive structure is provided in each of the above solutions. Based on such structure, no gap is generated in the first dielectric layer, which completely avoids a risk of connection between M1 and M2, and a distance between the trenches may be sufficiently small. In addition, because the trench-type resistive structure is embedded in the first dielectric layer, even if a size of the resistive structure is extremely small, the trench-type resistive structure does not fall off. Therefore, the trench-type resistive structure helps increase a quantity of the resistive structures in specific space, and increase a density of RRAM.

Other features and advantages of the embodiments of the present application will be described in detail in the subsequent specific implementation.

### BRIEF DESCRIPTION OF THE DRAWINGS

The drawings are used to provide further understanding of embodiments of the present application and constitute a part of the specification. The drawings and the following specific implementation are used to explain embodiments of the present application, but do not constitute a limitation on embodiments of the present application. In the drawings,

FIG. 1 is a schematic diagram of a stacked resistive structure;

FIG. 2 is a schematic diagram of a trench during a semiconductor manufacturing process according to a first embodiment of the present disclosure;

FIG. 3 is a schematic diagram of a bottom electrode during a semiconductor manufacturing process according to a first embodiment of the present disclosure;

FIG. 4 is a schematic diagram of a bottom electrode during a semiconductor manufacturing process according to a first embodiment of the present disclosure;

FIG. 5 is a schematic diagram of a resistive layer during a semiconductor manufacturing process according to a first embodiment of the present disclosure;

FIG. 6 is a schematic diagram of a top electrode during a semiconductor manufacturing process according to a first embodiment of the present disclosure;

FIG. 7 is a schematic structural diagram of a semiconductor device according to a first embodiment of the present disclosure;

FIG. 8 is a schematic diagram of a second dielectric layer or a thermally enhanced layer during a semiconductor manufacturing process according to a second embodiment of the present disclosure;

FIG. 9 is a schematic diagram of a second dielectric layer or a thermally enhanced layer during a semiconductor manufacturing process according to a second embodiment of the present disclosure;

FIG. 10 is a schematic diagram of a top electrode during a semiconductor manufacturing process according to a second embodiment of the present disclosure;

FIG. 11 is a schematic structural diagram of a semiconductor device according to a second embodiment of the present disclosure;

FIG. 12 is a schematic diagram of a top electrode during a semiconductor manufacturing process according to a third embodiment of the present disclosure;

FIG. 13 is a schematic diagram of a second dielectric layer during a semiconductor manufacturing process according to a third embodiment of the present disclosure;

FIG. 14 is a schematic structural diagram of a semiconductor device according to a third embodiment of the present disclosure;

FIG. 15 is a schematic diagram of a top electrode during a semiconductor manufacturing process according to a fourth embodiment of the present disclosure;

FIG. 16 is a schematic diagram of a second dielectric layer during a semiconductor manufacturing process according to a fourth embodiment of the present disclosure;

FIG. 17 is a schematic structural diagram of a semiconductor device according to a fourth embodiment of the present disclosure;

FIG. 18 is a schematic diagram of a thermally enhanced layer during a semiconductor manufacturing process according to a fifth embodiment of the present disclosure;

FIG. 19 is a schematic diagram of a thermally enhanced layer during a semiconductor manufacturing process according to a fifth embodiment of the present disclosure;

FIG. 20 is a schematic diagram of a top electrode during a semiconductor manufacturing process according to a fifth embodiment of the present disclosure; and

FIG. 21 is a schematic structural diagram of a semiconductor device according to a fifth embodiment of the present disclosure.

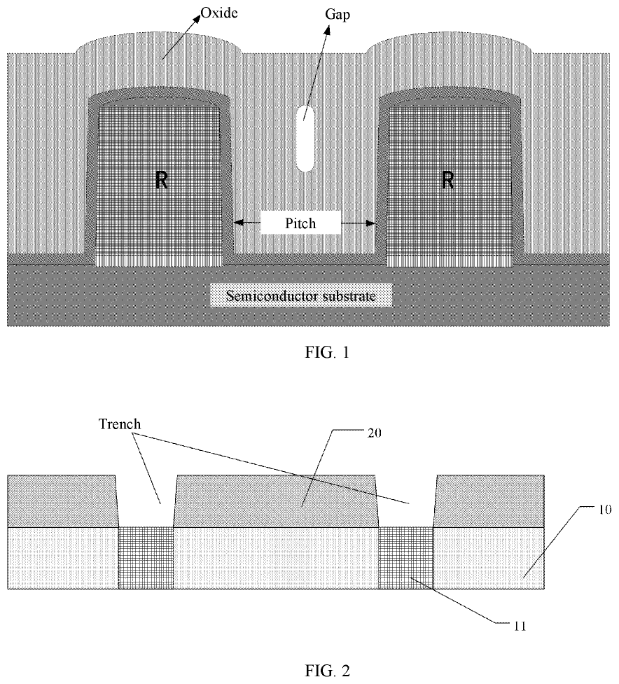

### DETAILED DESCRIPTION OF THE EMBODIMENTS

A specific implementation of embodiments of the present application is described in detail below with reference to the drawings. It should be understood that the specific implementation described herein is used only to describe and explain the embodiments of the present application, and is not used to limit the embodiments of the present application.

To solve a problem of a low RRAM density caused by a stacked resistive structure, the present disclosure provides a new semiconductor device of a trench-type resistive structure, and a method for manufacturing the semiconductor device.

Specific examples are used for description as follows.

### Embodiment 1

The present disclosure provides a method for manufacturing a semiconductor device. The method includes the following steps.

Step 101: Deposit a first dielectric layer material on a semiconductor substrate 10, and etch the first dielectric layer material, such that a trench corresponding to each via 11 in the semiconductor substrate 10 is formed in a first dielectric layer 20. The via 11 is filled with a metal material.

As shown in FIG. 2, there are two vias 11 in the semiconductor substrate 10 (there may be more vias in the semiconductor substrate 10, which are not shown in the drawings, and the two vias are used as an example in the present disclosure). Each via 11 is filled with the metal material and is configured to be connected to a bottom electrode.

First, the first dielectric layer material is deposited on the semiconductor substrate 10, and the first dielectric layer material is etched to form the first dielectric layer 20. The first dielectric layer 20 includes multiple trenches. The trench is corresponding to the via 11, and a width of a bottom of the trench is the same as a width of the via 11. The trench is formed by etching the first dielectric layer 20, such that an upper surface of the via 11 is exposed. Subsequently, when the bottom electrode is formed in the trench, the bottom electrode contacts the metal material of the via 11.

The first dielectric layer material in the present disclosure may be a nitride or an oxide. A material of the semiconductor substrate may be the oxide.

Step 102: Deposit a bottom electrode material in the trench, and etch the bottom electrode material to form a bottom electrode 30 covering the bottom of the trench.

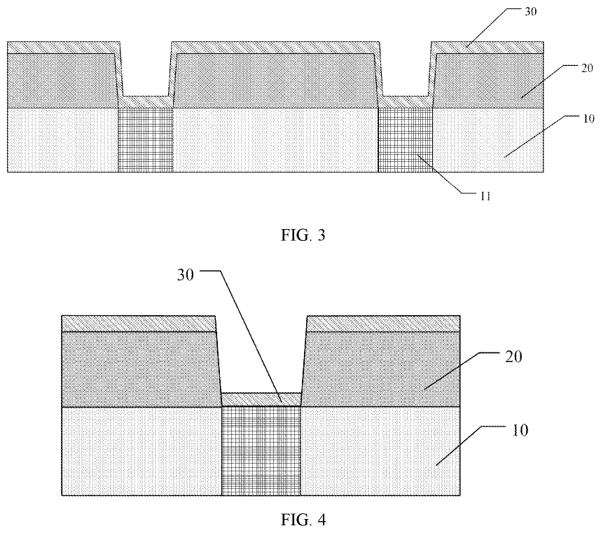

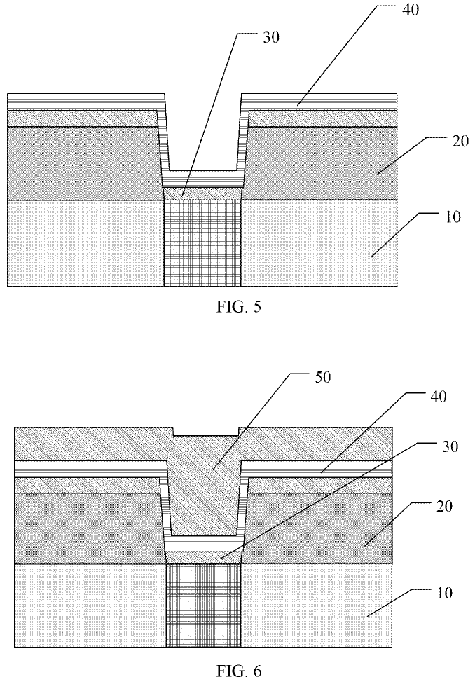

As shown in FIG. 3, after the trench is formed, the bottom electrode material is deposited. The bottom electrode material covers not only the trench, but also an upper surface of the first dielectric layer 20. For the trench, as shown in FIG. 4, the bottom electrode material that covers a sidewall is etched (by using isotropic etching (dry etching or wet etching)), to form the bottom electrode 30 that only covers the bottom of the trench. If the bottom electrode material on the sidewall of the trench is not etched, after a resistive structure is formed, the bottom electrode material on the sidewall is connected to a top electrode, such that the resistive structure is invalid.

It should be noted that, in this step, the bottom electrode material covering the upper surface of the first dielectric layer 20 is not etched temporarily, and is finally disposed of in a planarization manner.

One or more of titanium (Ti), tantalum (Ta), titanium nitride (TiN), and tantalum nitride (TaN) may be used for the bottom electrode material in the present disclosure.

Step 103: Deposit a resistive layer material to form a resistive layer 40 covering an upper surface of the bottom electrode 30 and the sidewall of the trench.

As shown in FIG. 5, after the bottom electrode 30 is formed, the resistive layer material is deposited to form the resistive layer 40. The resistive layer material in the present disclosure includes one or more of hafnium aluminum oxide (HfAlO), hafnium oxide (HfOx), alumina oxide (AlOx), and tantalum oxide (TaOx), which is not limited in the present disclosure.

The resistive layer 40 at the trench covers the upper surface of the bottom electrode 30 and the sidewall of the trench. The resistive layer 40 outside the trench further covers the upper surface of the bottom electrode material. The resistive layer 40 outside the trench is not etched temporarily, and is finally disposed of in a planarization manner.

Step 104: Deposit a top electrode material in a groove of the resistive layer 40, such that the groove is filled with the top electrode material to form a top electrode 50 which is arranged in the groove and fills the groove (i.e., the groove is full of the top electrode).

As shown in FIG. 5, a shape of the resistive layer 40 formed in the trench is similar to a shape of the trench. To distinguish from the trench formed in FIG. 2, the shape of the resistive layer 40 in the trench is referred to as the groove.

As shown in FIG. 6, the top electrode material is deposited in the groove of the resistive layer 40, such that the top electrode material fills the groove, and the formed top electrode 50 fills the groove.

One or more of titanium (Ti), tantalum (Ta), titanium nitride (TiN), and tantalum nitride (TaN) may be used for the top electrode material in the present disclosure.

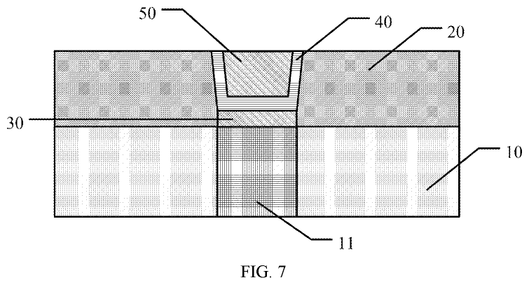

In an example, planarization may be performed, and the bottom electrode material, the resistive layer material, and the top electrode material on the first dielectric layer 20 are removed through grinding, such that the upper surface of the first dielectric layer 20 is flush with an upper surface of the resistive layer 40 and an upper surface of the top electrode 50 in the trench, to form a trench-type resistive structure shown in FIG. 7.

As shown in FIG. 7, a semiconductor device in this example includes: a semiconductor substrate 10, a first dielectric layer 20, a bottom electrode 30, a resistive layer 40, and a top electrode 50.

The semiconductor substrate 10 includes multiple vias 11 filled with a metal material.

The first dielectric layer 20 is arranged on the semiconductor substrate 10, multiple trenches are formed in the first dielectric layer 20, and the trenches are in a one-to-one correspondence with the vias 11.

The bottom electrode 30 covers a bottom of the trench, and a lower surface of the bottom electrode 30 contacts an upper surface of a corresponding via 11.

The resistive layer 40 covers an upper surface of the bottom electrode 30 and a sidewall of the trench.

The top electrode 50 is arranged in a groove of the resistive layer 40 and fills the groove.

An upper surface of the first dielectric layer 20 is flush with an upper surface of the resistive layer 40 and an upper surface of the top electrode 50 in the trench.

The trench-type resistive structure in this example includes: the bottom electrode 30, the resistive layer 40, and the top electrode 50.

### Embodiment 2

In this example, a method for manufacturing a semiconductor device is provided. The method includes:
step 101 to step 103, which are the same as step 101 to step 103 in Embodiment 1, and details are not described herein again. After step 103, steps 201 and 202 are performed.

Step 201: Deposit a second dielectric layer material or a thermally enhanced layer material in a groove of the resistive layer 40, and etch the second dielectric layer material or the thermally enhanced layer material to form a second dielectric layer 60 or a thermally enhanced layer 70 covering a sidewall of the groove.

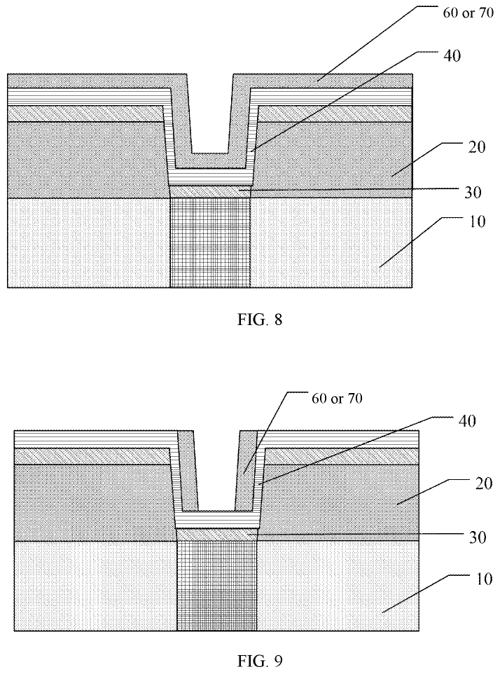

After step 101 to step 103 shown in FIG. 2 to FIG. 5, the bottom electrode 30 and the resistive layer 40 are successively formed in the trench. In this example, after the resistive layer 40 is formed, as shown in FIG. 8, the second dielectric layer material or the thermally enhanced layer material is deposited in the groove of the resistive layer 40, and the second dielectric layer material or the thermally enhanced layer material is etched to form the second dielectric layer 60 or the thermally enhanced layer 70 covering the sidewall of the groove. As shown in FIG. 9, the second dielectric layer material or the thermally enhanced layer material at a bottom of the trench is etched, and the second dielectric layer material or the thermally enhanced layer material outside the trench (i.e., the material on the resistive layer 40) is also etched, so as to form the second dielectric layer 60 or the thermally enhanced layer 70 covering only the sidewall of the groove of the resistive layer 40.

In this way, in the trench, a cavity is formed between the second dielectric layer 60 or the thermally enhanced layer 70 and the resistive layer 40.

In the present disclosure, the second dielectric layer material may be a nitride or an oxide, and the thermally enhanced layer material may be made of tantalum nitride (TaN).

Step 202: Fill a top electrode material in the cavity formed by the second dielectric layer 60 or the thermally enhanced layer 70 and the resistive layer 40 to form a top electrode 50.

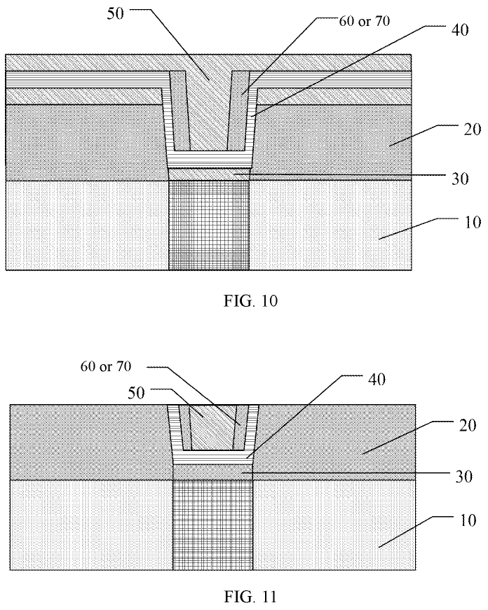

As shown in FIG. 10, the top electrode material is deposited, and in the trench, the top electrode material fills the cavity (i.e., the cavity is full of the top electrode material).

In an example, planarization may be performed, and the bottom electrode material, the resistive layer material, and the top electrode material on the first dielectric layer 20 are removed through grinding, such that an upper surface of the first dielectric layer 20 is flush with an upper surface of the resistive layer 40, an upper surface of the top electrode 50, and an upper surface of the second dielectric layer 60 or the thermally enhanced layer 70 in the trench, to obtain a trench-type resistive structure shown in FIG. 11.

As shown in FIG. 11, a semiconductor device in this example includes a semiconductor substrate 10, a first dielectric layer 20, a bottom electrode 30, a resistive layer 40, and a top electrode 50, and further includes a second dielectric layer 60 or a thermally enhanced layer 70.

The semiconductor substrate 10 includes multiple vias 11 filled with a metal material.

The first dielectric layer 20 is arranged on the semiconductor substrate 10, multiple trenches are formed in the first dielectric layer 20, and the trenches are in a one-to-one correspondence with the vias 11.

The bottom electrode 30 covers a bottom of the trench, and a lower surface of the bottom electrode 30 contacts an upper surface of a corresponding via 11.

The resistive layer 40 covers an upper surface of the bottom electrode 30 and a sidewall of the trench.

The second dielectric layer 60 or the thermally enhanced layer 70 covers a sidewall of a groove of the resistive layer 40, and a cavity is formed.

The top electrode 50 is arranged in the cavity and fills the cavity.

An upper surface of the first dielectric layer 20 is flush with an upper surface of the resistive layer 40, an upper surface of the top electrode 50, and an upper surface of the second dielectric layer 60 or the thermally enhanced layer 70 in the trench.

The trench-type resistive structure in this example includes: the bottom electrode 30, the resistive layer 40, the top electrode 50, and the second dielectric layer 60 or the thermally enhanced layer 70.

### Embodiment 3

In this example, a method for manufacturing a semiconductor device is provided. The method includes:
step 101 to step 103, which are the same as step 101 to step 103 in Embodiment 1, and details are not described herein again. After step 103, step 301 and step 302 are performed.

Step 301: Deposit a top electrode material in a groove of the resistive layer 40 to form a top electrode 50 covering a bottom and a sidewall of the groove of the resistive layer 40.

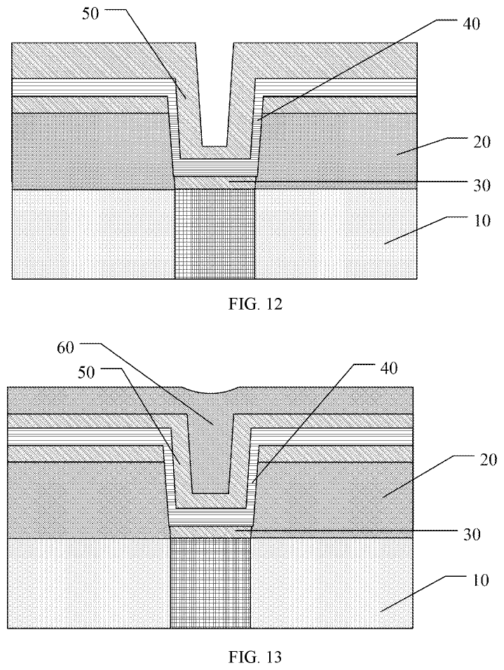

After step 101 to step 103 shown in FIG. 2 to FIG. 5, the bottom electrode 30 and the resistive layer 40 are successively formed in the trench. In this example, after the resistive layer 40 is formed, as shown in FIG. 12, the top electrode material is deposited in the groove of the resistive layer 40, to form the top electrode 50 covering the bottom and the sidewall of the groove of the resistive layer 40. The top electrode material on the outside of the trench (i.e., the material on the resistive layer 40) is not etched temporarily, and is subsequently disposed of in a planarization manner.

Step 302: Fill a second dielectric layer material in a groove of the top electrode 50 to form a second dielectric layer 60.

As shown in FIG. 12, a shape of the top electrode 50 in the trench is similar to a shape of the trench. To distinguish from the trench, the shape of the top electrode 50 in the trench in this example is referred to as the groove. As shown in FIG. 13, the second dielectric layer material is filled in the groove of the top electrode 50 to form the second dielectric layer 60.

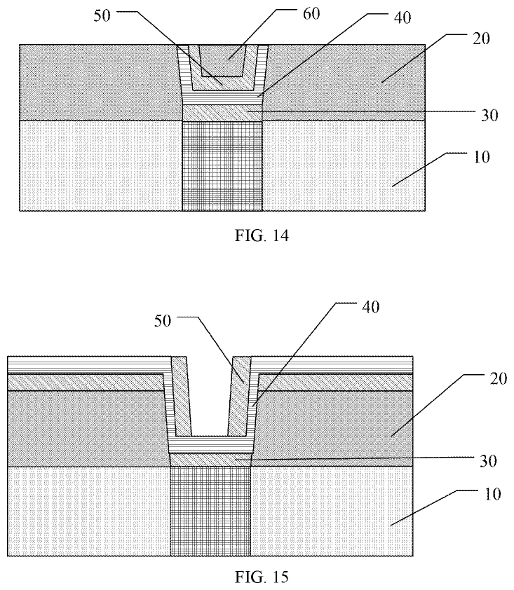

Then, planarization is performed, and the bottom electrode material, the resistive layer material, the top electrode material, and the second dielectric layer material on the first dielectric layer 20 are removed through grinding, such that an upper surface of the first dielectric layer 20 is flush with an upper surface of the resistive layer 40, an upper surface of the top electrode 50, and an upper surface of the second dielectric layer 60 in the trench, to obtain a trench-type resistive structure shown in FIG. 14.

As shown in FIG. 14, a semiconductor device in this example includes: a semiconductor substrate 10, a first dielectric layer 20, a bottom electrode 30, a resistive layer 40, a top electrode 50, and a second dielectric layer 60.

The semiconductor substrate 10 includes multiple vias filled with a metal material.

The first dielectric layer 20 is arranged on the semiconductor substrate 10, multiple trenches are formed in the first dielectric layer 20, and the trenches are in a one-to-one correspondence with the vias.

The bottom electrode 30 covers a bottom of the trench, and a lower surface of the bottom electrode 30 contacts an upper surface of a corresponding via.

The resistive layer 40 covers an upper surface of the bottom electrode 30 and a sidewall of the trench.

The top electrode 50 covers a bottom and a sidewall of a groove of the resistive layer 40.

The second dielectric layer 60 is filled in a groove of the top electrode 50.

An upper surface of the first dielectric layer 20 is flush with an upper surface of the resistive layer 40, an upper surface of the top electrode 50, and an upper surface of the second dielectric layer 60 in the trench.

The trench-type resistive structure in this example includes: the bottom electrode 30, the resistive layer 40, the top electrode 50, and the second dielectric layer 60.

### Embodiment 4

In this example, a method for manufacturing a semiconductor device is provided. The method includes:
step 101 to step 103, which are the same as step 101 to step 103 in Embodiment 1, and details are not described herein again. Step 401 and step 402 are performed after step 103.

Step 401: Deposit a top electrode material in a groove of the resistive layer 40, and etch the top electrode material to form a top electrode 50 covering a sidewall of the groove of the resistive layer 40.

After step 101 to step 103 shown in FIG. 2 to FIG. 5, the bottom electrode 30 and the resistive layer 40 are successively formed in the trench. In this example, after the resistive layer 40 is formed, as shown in FIG. 12, the top electrode material is deposited in the groove of the resistive layer 40. After etching is performed, the top electrode 50 covering the sidewall of the groove of the resistive layer 40 is formed, as shown in FIG. 15. In this example, when etching is performed, only the top electrode material on the sidewall of the groove of the resistive layer 40 is reserved, and the top electrode material at a bottom of the groove of the resistive layer 40 and the top electrode material outside the groove of the resistive layer 40 are removed through etching.

Step 402: Fill a second dielectric layer material in a cavity formed by the top electrode 50 and the resistive layer 40 to form a second dielectric layer 60.

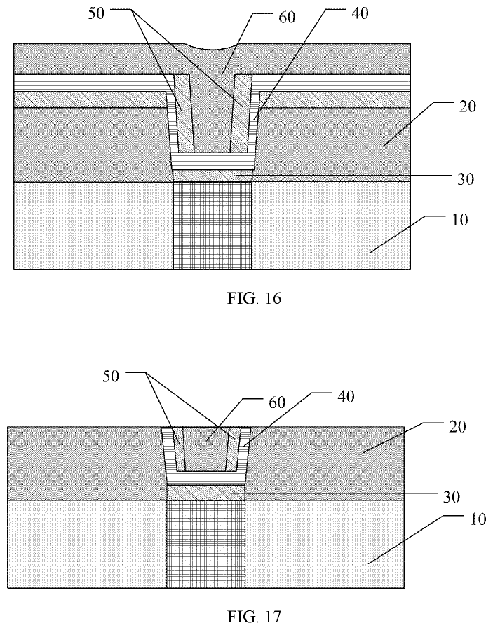

As shown in FIG. 15, the cavity is formed between the top electrode 50 formed by etching and the resistive layer 40. As shown in FIG. 16, the second dielectric layer material is filled in the cavity to form the second dielectric layer 60.

Then, planarization is performed, and the bottom electrode material, the resistive layer material, and the second dielectric layer material on the first dielectric layer 20 are removed through grinding, such that an upper surface of the first dielectric layer 20 is flush with an upper surface of the resistive layer 40, an upper surface of the top electrode 50, and an upper surface of the second dielectric layer 60 in the trench, to obtain a trench-type resistive structure shown in FIG. 17.

As shown in FIG. 17, a semiconductor device in this example includes: a semiconductor substrate 10, a first dielectric layer 20, a bottom electrode 30, a resistive layer 40, a top electrode 50, and a second dielectric layer 60.

The semiconductor substrate 10 includes multiple vias 11 filled with a metal material.

The first dielectric layer 20 is arranged on the semiconductor substrate 10, multiple trenches are formed in the first dielectric layer 20, and the trenches are in a one-to-one correspondence with the vias 11.

The bottom electrode 30 covers a bottom of the trench, and a lower surface of the bottom electrode 30 contacts an upper surface of a corresponding via 11.

The resistive layer 40 covers an upper surface of the bottom electrode 30 and a sidewall of the trench.

The top electrode 50 covers a sidewall of a groove of the resistive layer 40.

The second dielectric layer 60 is filled in a cavity formed by the top electrode 50 and the resistive layer 40.

An upper surface of the first dielectric layer 20 is flush with an upper surface of the resistive layer 40, an upper surface of the top electrode 50, and an upper surface of the second dielectric layer 60 in the trench.

The trench-type resistive structure in this example includes: the bottom electrode 30, the resistive layer 40, the top electrode 50, and the second dielectric layer 60.

### Embodiment 5

In this example, a method for manufacturing a semiconductor device is provided. The method includes:
step 101 to step 103, which are the same as step 101 to step 103 in Embodiment 1, and details are not described herein again. Steps 501-502 are performed after step 103.

Step 501: Deposit a thermally enhanced layer material in a groove of the resistive layer 40 to form a thermally enhanced layer 70 covering a bottom and a sidewall of the groove of the resistive layer 40.

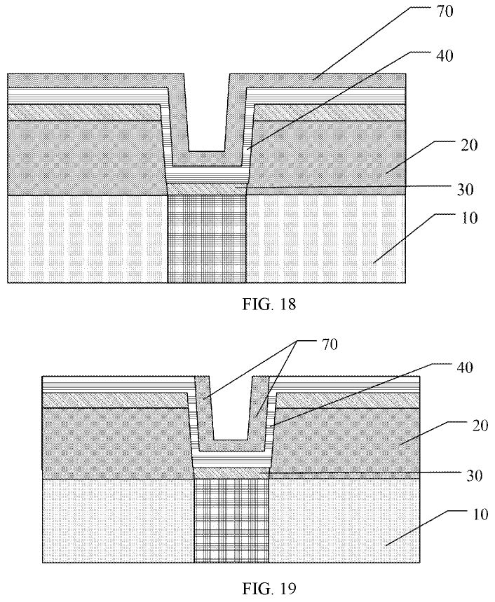

After step 101 to step 103 shown in FIG. 2 to FIG. 5, the bottom electrode 30 and the resistive layer 40 are successively formed in the trench. In this example, after the resistive layer 40 is formed, as shown in FIG. 18, the thermally enhanced layer material is deposited in the groove of the resistive layer 40. After etching is performed, the thermally enhanced layer 70 covering the bottom and the sidewall of the groove of the resistive layer 40 is formed. In this example, the thermally enhanced layer material outside the trench is etched to form the thermally enhanced layer 70 shown in FIG. 19.

Step 502: Fill a top electrode material in a groove of the thermally enhanced layer 70 to form a top electrode 50.

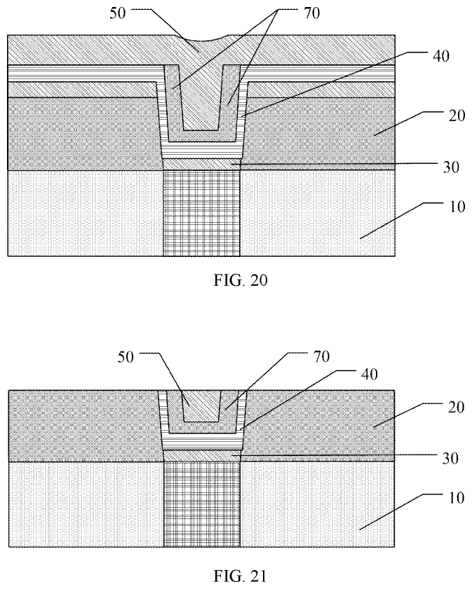

As shown in FIG. 20, the top electrode material is filled in the groove of the thermally enhanced layer 70 to form the top electrode 50.

Then, planarization is performed, and the bottom electrode material, the resistive layer material, and the top electrode material on the first dielectric layer 20 are removed through grinding, such that an upper surface of the first dielectric layer 20 is flush with an upper surface of the resistive layer 40, an upper surface of the top electrode 50, and an upper surface of the thermally enhanced layer 70 in the trench, to obtain a trench-type resistive structure shown in FIG. 21.

As shown in FIG. 21, a semiconductor device in this example includes: a semiconductor substrate 10, a first dielectric layer 20, a bottom electrode 30, a resistive layer 40, a top electrode 50, and a thermally enhanced layer 70.

The semiconductor substrate 10 includes multiple vias 11 filled with a metal material.

The first dielectric layer 20 is arranged on the semiconductor substrate 10, multiple trenches are formed in the first dielectric layer 20, and the trenches are in a one-to-one correspondence with the vias 11.

The bottom electrode 30 covers a bottom of the trench, and a lower surface of the bottom electrode 30 contacts an upper surface of a corresponding via 11.

The resistive layer 40 covers an upper surface of the bottom electrode 30 and a sidewall of the trench.

The thermally enhanced layer 70 covers a bottom and a sidewall of a groove of the resistive layer 40.

The top electrode 50 is filled in a groove of the thermally enhanced layer 70.

An upper surface of the first dielectric layer 20 is flush with an upper surface of the resistive layer 40, an upper surface of the top electrode 50, and an upper surface of the thermally enhanced layer 70 in the trench.

The trench-type resistive structure in this example includes: the bottom electrode 30, the resistive layer 40, the top electrode 50, and the thermally enhanced layer 70.

The trench-type resistive structure is provided in each of the above examples. Based on such structure, the first dielectric layer 20 (that is, the oxide in the background) is first deposited, and the trench is formed through etching in the first dielectric layer 20 to bear the resistive structure. Before the trench is formed, deposition of the first dielectric layer material on the entire flat semiconductor substrate 10 is completed, and no gap is generated in the first dielectric layer 20. Therefore, after the trench is formed through etching, no new gap is generated in the first dielectric layer 20, which completely avoids a risk of connection between M1 and M2. Therefore, a distance between trenches may be sufficiently small. In addition, because the trench-type resistive structure is embedded in the first dielectric layer 20, even if a size of the resistive structure is extremely small, the resistive structure does not fall off because the resistive structure is entirely supported by the first dielectric layer 20. Therefore, the trench-type resistive structure helps increase a quantity of the resistive structures in specific space, and increase a density of RRAM.

It should be noted that, in this specification, the term “include”, “comprise”, or any other variant thereof is intended to cover a non-exclusive inclusion, such that a process, a method, an article, or an apparatus that includes a list of elements not only includes those elements but also includes other elements which are not expressly listed, or further includes elements inherent to such process, method, article, or apparatus. In absence of more constraints, an element limited by “includes a . . . ” does not preclude the existence of other identical elements in the process, method, article, or apparatus that includes the element.

The above descriptions are intended to enable any person skilled in the art to implement and use content of the present disclosure and are provided in the context of an application and requirements for the specific application. In addition, the above descriptions of the embodiments of the present disclosure are provided for illustration and description only. The above descriptions are not intended to limit the present disclosure to the disclosed form in detail. Therefore, many modifications and variations will be apparent to those skilled in the art, and general principles defined herein may be applied to other embodiments and applications without departing from the substance and scope of the present disclosure. Furthermore, description of the above embodiments is not intended to limit the present disclosure. Therefore, the present disclosure is not intended to be limited to the embodiments shown, but will be given the widest range consistent with the principles and features disclosed herein.

What is claimed is:

1. A method for manufacturing a semiconductor device, comprising:
depositing a first dielectric layer material on a semiconductor substrate, and etching the first dielectric layer material to form a trench corresponding to each via in the semiconductor substrate in a first dielectric layer, the via being filled with a metal material;
depositing a bottom electrode material in the trench, and etching the bottom electrode material to form a bottom electrode covering a bottom of the trench;
depositing a resistive layer material to form a resistive layer covering an upper surface of the bottom electrode and a sidewall of the trench; and
depositing a top electrode material in a groove of the resistive layer, wherein the groove is filled with the top electrode material to form a top electrode, wherein the top electrode is arranged in the groove and fills the groove.

2. The method according to claim 1, further comprising:
performing planarization, wherein an upper surface of the first dielectric layer is flush with an upper surface of the resistive layer and an upper surface of the top electrode in the trench.

3. A semiconductor device manufactured by the method according to claim 1, comprising: a semiconductor substrate, a first dielectric layer, a bottom electrode, a resistive layer, and a top electrode; wherein
the semiconductor substrate comprises a plurality of vias filled with a metal material;
the first dielectric layer is arranged on the semiconductor substrate, a plurality of trenches are formed in the first dielectric layer, and the plurality of trenches are in a one-to-one correspondence with the plurality of vias;
the bottom electrode covers a bottom of the trench, and a lower surface of the bottom electrode contacts an upper surface of a corresponding via;
the resistive layer covers an upper surface of the bottom electrode and a sidewall of the trench; and
the top electrode is arranged in a groove of the resistive layer and fills the groove.

4. The semiconductor device according to claim 3, wherein an upper surface of the first dielectric layer is flush with an upper surface of the resistive layer and an upper surface of the top electrode in the trench.

5. A method for manufacturing a semiconductor device, comprising:
depositing a first dielectric layer material on a semiconductor substrate, and etching the first dielectric layer material to form a trench corresponding to each via in the semiconductor substrate in a first dielectric layer, the via being filled with a metal material;
depositing a bottom electrode material in the trench, and etching the bottom electrode material to form a bottom electrode covering a bottom of the trench;
depositing a resistive layer material to form a resistive layer covering an upper surface of the bottom electrode and a sidewall of the trench;
depositing a second dielectric layer material or a thermally enhanced layer material in a groove of the resistive layer, and etching the second dielectric layer material or the thermally enhanced layer material to form a second dielectric layer or a thermally enhanced layer covering a sidewall of the groove; and
filling a top electrode material in a cavity formed by the second dielectric layer or the thermally enhanced layer and the resistive layer to form a top electrode.

6. The method according to claim 5, further comprising:
performing planarization, wherein an upper surface of the first dielectric layer is flush with an upper surface of the resistive layer, an upper surface of the top electrode, and an upper surface of the second dielectric layer or the thermally enhanced layer in the trench.

7. A semiconductor device manufactured by the method according to claim 5, comprising: a semiconductor substrate, a first dielectric layer, a bottom electrode, a resistive layer, and a top electrode; and further comprising a second dielectric layer or a thermally enhanced layer; wherein
the semiconductor substrate comprises a plurality of vias filled with a metal material;
the first dielectric layer is arranged on the semiconductor substrate, a plurality of trenches are formed in the first dielectric layer, and the plurality of trenches are in a one-to-one correspondence with the plurality of vias;
the bottom electrode covers a bottom of the trench, and a lower surface of the bottom electrode contacts an upper surface of a corresponding via;
the resistive layer covers an upper surface of the bottom electrode and a sidewall of the trench;
the second dielectric layer or the thermally enhanced layer covers a sidewall of a groove of the resistive layer, and a cavity is formed; and
the top electrode is arranged in the cavity and fills the cavity.

8. The semiconductor device according to claim 7, wherein an upper surface of the first dielectric layer is flush with an upper surface of the resistive layer, an upper surface of the top electrode, and an upper surface of the second dielectric layer or the thermally enhanced layer in the trench.

9. A method for manufacturing a semiconductor device, comprising:
depositing a first dielectric layer material on a semiconductor substrate, and etching the first dielectric layer material to form a trench corresponding to each via in the semiconductor substrate in a first dielectric layer, the via being filled with a metal material;
depositing a bottom electrode material in the trench, and etching the bottom electrode material to form a bottom electrode covering a bottom of the trench;
depositing a resistive layer material to form a resistive layer covering an upper surface of the bottom electrode and a sidewall of the trench;
depositing a top electrode material in a groove of the resistive layer to form a top electrode covering a bottom and a sidewall of the groove of the resistive layer; and
filling a second dielectric layer material in a groove of the top electrode to form a second dielectric layer.

10. The method according to claim 9, further comprising:
performing planarization, wherein an upper surface of the first dielectric layer is flush with an upper surface of the resistive layer, an upper surface of the top electrode, and an upper surface of the second dielectric layer in the trench.

11. A semiconductor device manufactured by the method according to claim 9, comprising: a semiconductor substrate, a first dielectric layer, a bottom electrode, a resistive layer, a top electrode, and a second dielectric layer; wherein
the semiconductor substrate comprises a plurality of vias filled with a metal material;
the first dielectric layer is arranged on the semiconductor substrate, a plurality of trenches are formed in the first dielectric layer, and the plurality of trenches are in a one-to-one correspondence with the plurality of vias;
the bottom electrode covers a bottom of the trench, and a lower surface of the bottom electrode contacts an upper surface of a corresponding via;
the resistive layer covers an upper surface of the bottom electrode and a sidewall of the trench;
the top electrode covers a bottom and a sidewall of a groove of the resistive layer; and
the second dielectric layer is filled in a groove of the top electrode.

12. The semiconductor device according to claim 11, wherein an upper surface of the first dielectric layer is flush with an upper surface of the resistive layer, an upper surface of the top electrode, and an upper surface of the second dielectric layer in the trench.

13. A method for manufacturing a semiconductor device, comprising:
depositing a first dielectric layer material on a semiconductor substrate, and etching the first dielectric layer material to form a trench corresponding to each via in the semiconductor substrate in a first dielectric layer, the via being filled with a metal material;
depositing a bottom electrode material in the trench, and etching the bottom electrode material to form a bottom electrode covering a bottom of the trench;
depositing a resistive layer material to form a resistive layer covering an upper surface of the bottom electrode and a sidewall of the trench;
depositing a top electrode material in a groove of the resistive layer, and etching the top electrode material to form a top electrode covering a sidewall of the groove of the resistive layer; and
filling a second dielectric layer material in a cavity formed by the top electrode and the resistive layer to form a second dielectric layer.

14. The method according to claim 13, further comprising:
performing planarization, wherein an upper surface of the first dielectric layer is flush with an upper surface of the resistive layer, an upper surface of the top electrode, and an upper surface of the second dielectric layer in the trench.

15. A semiconductor device manufactured by the method according to claim 13, comprising: a semiconductor substrate, a first dielectric layer, a bottom electrode, a resistive layer, a top electrode, and a second dielectric layer; wherein
the semiconductor substrate comprises a plurality of vias filled with a metal material;
the first dielectric layer is arranged on the semiconductor substrate, a plurality of trenches are formed in the first dielectric layer, and the plurality of trenches are in a one-to-one correspondence with the plurality of vias;
the bottom electrode covers a bottom of the trench, and a lower surface of the bottom electrode contacts an upper surface of a corresponding via;
the resistive layer covers an upper surface of the bottom electrode and a sidewall of the trench;
the top electrode covers a sidewall of a groove of the resistive layer; and
the second dielectric layer is filled in a cavity formed by the top electrode and the resistive layer.

16. The semiconductor device according to claim 15, wherein an upper surface of the first dielectric layer is flush with an upper surface of the resistive layer, an upper surface of the top electrode, and an upper surface of the second dielectric layer in the trench.

17. A method for manufacturing a semiconductor device, comprising:
depositing a first dielectric layer material on a semiconductor substrate, and etching the first dielectric layer material to form a trench corresponding to each via in the semiconductor substrate in a first dielectric layer, the via being filled with a metal material;
depositing a bottom electrode material in the trench, and etching the bottom electrode material to form a bottom electrode covering a bottom of the trench;
depositing a resistive layer material to form a resistive layer covering an upper surface of the bottom electrode and a sidewall of the trench;
depositing a thermally enhanced layer material in a groove of the resistive layer to form a thermally enhanced layer covering a bottom and a sidewall of the groove of the resistive layer; and
filling a top electrode material in a groove of the thermally enhanced layer to form a top electrode.

18. The method according to claim 17, further comprising:
performing planarization, wherein an upper surface of the first dielectric layer is flush with an upper surface of the resistive layer, an upper surface of the top electrode, and an upper surface of the thermally enhanced layer in the trench.

19. A semiconductor device manufactured by the method according to claim 17, comprising: a semiconductor substrate, a first dielectric layer, a bottom electrode, a resistive layer, a top electrode, and a thermally enhanced layer; wherein
the semiconductor substrate comprises a plurality of vias filled with a metal material;
the first dielectric layer is arranged on the semiconductor substrate, a plurality of trenches are formed in the first dielectric layer, and the plurality of trenches are in a one-to-one correspondence with the plurality of vias;
the bottom electrode covers a bottom of the trench, and a lower surface of the bottom electrode contacts an upper surface of a corresponding via;
the resistive layer covers an upper surface of the bottom electrode and a sidewall of the trench;
the thermally enhanced layer covers a bottom and a sidewall of a groove of the resistive layer; and
the top electrode is filled in a groove of the thermally enhanced layer.

20. The semiconductor device according to claim 19, wherein an upper surface of the first dielectric layer is flush with an upper surface of the resistive layer, an upper surface of the top electrode, and an upper surface of the thermally enhanced layer in the trench.
